(19) United States
(12) Patent Application Publication
(10) Pub. No.: US 2007/0063786 A1
(43) Pub. Date: Mar. 22, 2007

(54) Balanced-to-unbalanced converter

(75) Inventor: Cheng-Yen Shih, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/516,547

(22) Filed: Sep. 7, 2006

(30) Foreign Application Priority Data
Sep. 22, 2005 (TW) 094132764

(51) Int. Cl. H03H 7/42

(52) U.S. Cl. 333/25

(57) ABSTRACT

A balanced-to-unbalanced converter includes a transformer and a bias feeding circuit. The transformer has an unbalanced signal input/output (I/O) circuit and a balanced signal I/O circuit. The bias feeding circuit is electrically connected with the balanced signal I/O circuit of the transformer. The balanced-to-unbalanced converter equips with the bias feeding function, and thus the extra bias feeding circuit, which provides the operating power for the active component, is unnecessary in the system with the balanced-to-unbalanced converter.

### BACKGROUND OF THE INVENTION

1. Field of Invention

The invention relates to a balanced-to-unbalanced converter (Balun) and, in particular, to a balanced-to-unbalanced converter with a bias feeding function.

2. Related Art

FIG. 1A is a schematic diagram showing a conventional mobile telecommunication system. With reference to FIG. 1A, a conventional mobile telecommunication system 10 includes an antenna 12, a front end module 14, and a transceiver 16. The front end module 14 includes a transmit-receive (T-R) switch 18, a Balun 20, a band-pass filter (BPF) 22, and a low-pass filter (LPF) 24. In addition, transceiver 16 includes a receiving amplifier 26 and a transmitting amplifier 28.

The antenna 12 transmits a wireless signal to the T-R switch 18 of the front end module 14 when the mobile communication system 10 received the wireless signal. At this moment, the T-R switch 18 is switched to a receiving mode and the wireless signal is transmitted to the band-pass filter 22 through the T-R switch 18. The band-pass filter 22 is used to filter out the signal except a particular band and the Balun 20 transforms the signal with a particular band into a balanced signal, which is transmitted to the receiving amplifier 26 of the transceiver 16. The receiving amplifier 26 is to amplify the balanced signal that can be heard. In contrary, the balanced signal is transmitted to the low-pass filter 24 through the transmitting amplifier 28 when the mobile communication system 10 wants to transmit the balanced signal to the exterior. The transmitting amplifier 28 is used to amplify the balanced signal and then the low-pass filter 24 transmits the balanced signal to the T-R switch 18 after filtering out the balanced signal except a particular band. At this moment, the T-R switch 18 is switched to a transmitting mode and the balanced signal with a particular band is transmitted to the antenna 12 through the T-R switch 18 so as to transmit the balanced signal with the particular band to the exterior.

Referring to FIG. 1B, the conventional Balun 20 commonly transforms the signal between the balanced signal and the unbalanced signal by utilizing a transformer. However, due to the operating power supplied to the receiving amplifier 26, a bias circuit 30 is commonly disposed between the Balun 20 and the receiving amplifier 26 to feed the operating power for the receiving amplifier 26. The bias circuit 30 includes two alternating current (AC) signal isolating circuits 32 and 34, which are composed by one or multiplesets of capacitor and inductor respectively. Normally, the operating power of the receiving amplifier 26 may be the direct current (DC) power. Therefore, the AC signal isolating circuits 32 and 34 can prevent the AC signal from Balun 20 leakage to bias circuit 30. Additionally, the bias circuit 30 may include capacitors C1 and C2 in order to prevent the bias signal which is from the inputting terminals S1 and S2 shorted by the Balun 20, and to avoid the system breakdown.

As mentioned above, the conventional art disposes the bias circuit 30 between the Balun 20 and the receiving amplifier 26 so that not only can the material cost increase, but also the space occupied by the component increases. Additionally, the bias circuit 30 interferes with the signal transmitted within the system, which increases the insertion loss of the system. Herein, the insertion loss means a ratio of the input signal to the output signal. Thus, it is an important subject to decrease the number of the components for reducing the cost and to lower the insertion loss of the system with the Balun.

### SUMMARY OF THE INVENTION

In view of the foregoing, the invention is used to provide a Balun with a bias feeding function for reducing the manufacturing cost and the insertion loss of a system.

To achieve the above, a balanced-to-unbalanced converter of the invention includes a transformer and a bias feeding circuit. The transformer has an unbalanced signal input/output (I/O) circuit and a balanced signal I/O circuit. The bias feeding circuit is electrically connected to the balanced signal I/O circuit of the transformer.

As mentioned above, the balanced-to-unbalanced converter of the invention integrates the bias feeding circuit with the conventional Balun, so that the AC isolating circuit for the bias feeding circuit is unnecessary. Therefore, the component cost can be reduced, the space for the component can be avoided, and the insertion loss can be decreased.

### BRIEF DESCRIPTION OF THE DRAWINGS

The invention will become more fully understood from the detailed description given herein below illustration only, and thus is not limitative of the present invention, and wherein:

FIG. 1A is a schematic diagram showing a conventional mobile communication system;

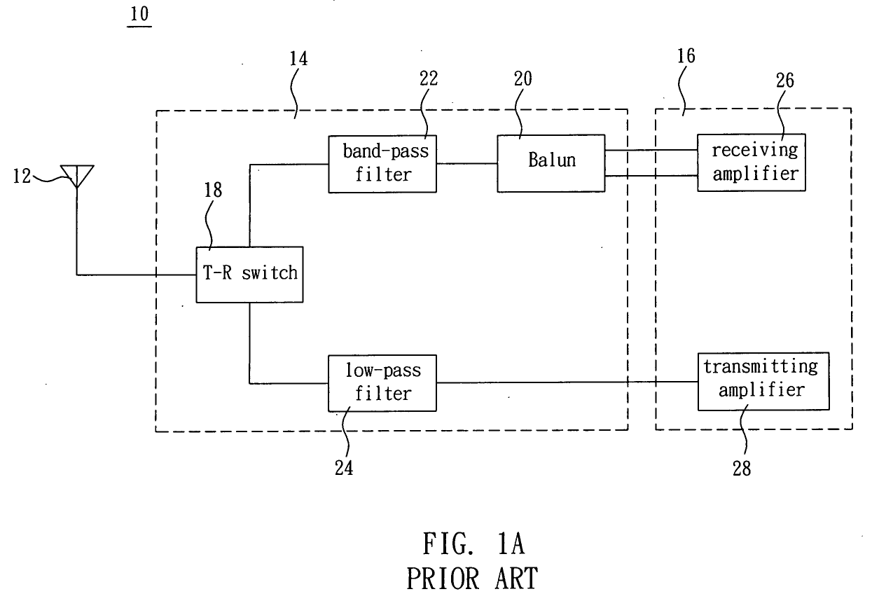

FIG. 1B is a schematic diagram showing a part of the conventional mobile communication system;

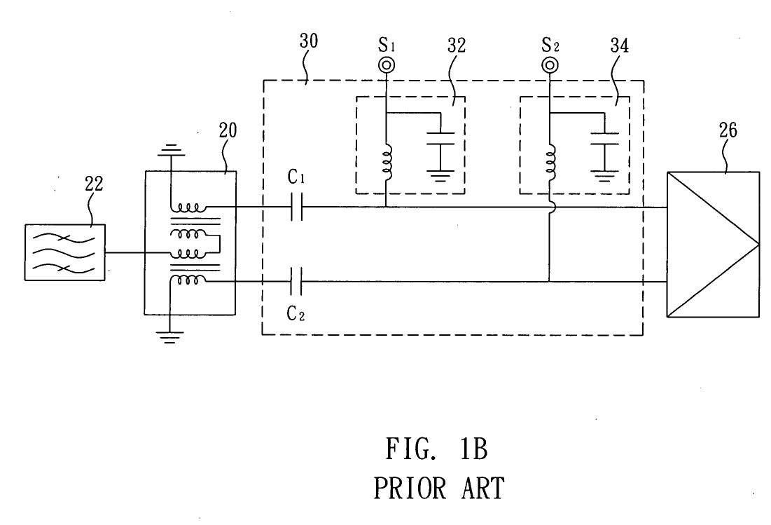

FIG. 2 is a schematic diagram showing a balanced-to-unbalanced converter according to an embodiment of the invention; and

FIG. 3 is an application diagram showing the balanced-to-unbalanced converter according to the embodiment of the invention.

### DETAILED DESCRIPTION OF THE INVENTION

The present invention will be apparent from the following detailed description, which proceeds with reference to the accompanying drawings, wherein the same references relate to the same elements.

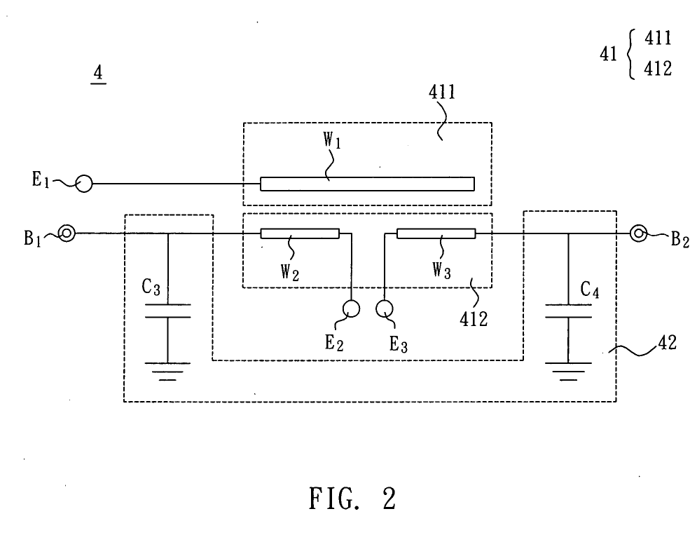

Referring to FIG. 2, a balanced-to-unbalanced converter 4 according to an embodiment of the invention can be applied to an antenna system. The balanced-to-unbalanced converter 4 includes a transformer 41 and a bias feeding circuit 42. In the embodiment, the transformer 41 and the bias feeding circuit 42 can be made with the Low-Temperature Co-fired Ceramics (LTCC) technique.

The transformer 41 has an unbalanced signal I/O circuit 411 and a balanced signal I/O circuit 412. In the embodiment, the unbalanced signal I/O circuit 411 includes a first winding W₁, and the balanced signal I/O circuit 412 includes a second winding W₂ and a third winding W₃. The first winding W₁ is coupled to the second winding W₂ and the third winding W₃, respectively. In the embodiment, the first winding W₁ has an unbalanced signal I/O terminal E₁, the second winding W₂ has a first balanced signal I/O terminal E₂, and the third winding W₃ has a second balanced signal I/O terminal E₃.

The bias feeding circuit 42 is electrically connected to the balanced signal I/O circuit 412 of the transformer 41. Moreover, the bias feeding circuit 42 includes a first bias feeding terminal B₁, a second bias feeding terminal B₂ and at least one capacitor cooperating to the transformer 41. In this embodiment, the bias feeding circuit 42 includes a first capacitor C₃ and a second capacitor C₄. One end of the first capacitor C₃ is electrically connected to one end of the second winding W₂ and the first bias feeding terminal B₁, respectively, and the first capacitor C₃ is cooperated to the second winding W₂ to isolate the AC signal or the high frequency signal received by the balanced-to-unbalanced converter 4 leakage to the first bias feeding terminal B₁. One end of the second capacitor C₄ is electrically connected to one end of the third winding W₃ and the second bias feeding terminal B₂, respectively, and the second capacitor C4 is cooperated to the third winding W₃ to isolate the AC signal or the high frequency signal received by the balanced-to-unbalanced converter 4 leakage to the second bias feeding terminal B₂. Furthermore, another end of each of the first capacitor C₃ and the second capacitor C₄ is electrically connected to a ground.

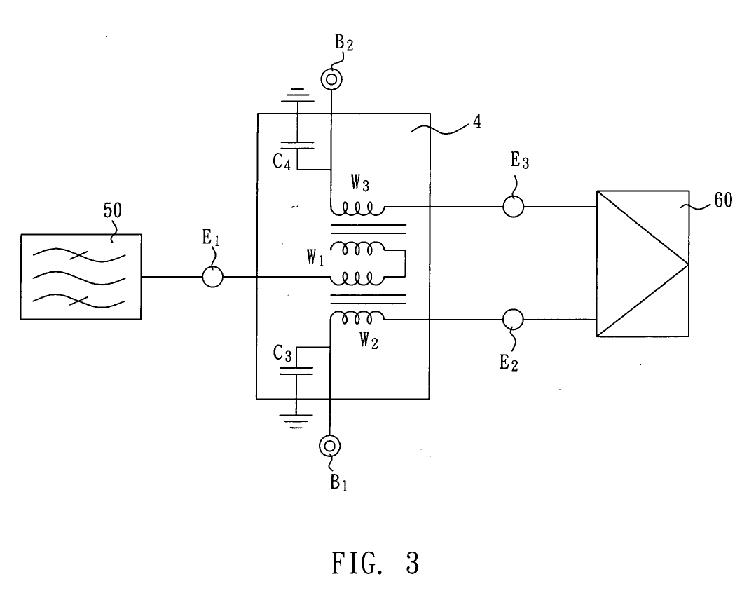

FIG. 3 is an application diagram showing the balanced-to-unbalanced converter according to the embodiment of the invention. With reference to FIG. 3, the balanced-to-unbalanced converter 4 is disposed between a filter 50 and an active component 60, and the balanced-to-unbalanced converter 4 has the impendence matching function, the balanced and unbalanced signal converting functions, and the balanced and unbalanced signal transmitting functions. In this embodiment, the filter 50 can be a band-pass filter and the active component 60 can be an amplifier or a wireless transceiver.

In this embodiment, the unbalanced signal I/O terminal E₁ of the first winding W₁ is electrically connected to the filter 50, and the first balanced signal I/O terminal E₂ of the second winding W₂ and the second balanced signal I/O terminal E₃ of the third winding W₃ are electrically connected to the active component 60, respectively. The bias, which the active component 60 needs, is inputted into the balanced-to-unbalanced converter 4 through the first bias feeding point B₁ and the second bias feeding point B₂, respectively. Then, the bias is provided to the active component 60 through the first balanced signal I/O terminal E₂ and the second balanced signal I/O terminal E₃.

In summary, the balanced-to-unbalanced converter of the invention equips with the bias feeding function, and thus the extra bias feeding circuit, which provides the operating power for the active component, is unnecessary in the system with the balanced-to-unbalanced converter. The operating power can be fed into the balanced-to-unbalanced converter directly, and the conventional AC isolating circuit can be omitted for reducing the component cost, lessening the space occupied by the component, and decreasing the insertion loss so as to enhance the system performance.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A balanced-to-unbalanced converter, comprising:
a transformer having a unbalanced signal input/output (I/O) circuit and a balanced signal I/O circuit; and
a bias feeding circuit electrically connected to the balanced signal I/O circuit.

2. The converter according to claim 1, wherein the transformer and the bias feeding circuit is manufactured with Low-Temperature Co-fired Ceramics (LTCC).

3. The converter according to claim 1, wherein the unbalanced signal I/O circuit comprises a first winding, and the balanced signal I/O circuit comprises a second winding and a third winding, both of which are coupled to the first winding, respectively.

4. The converter according to claim 3, wherein the bias feeding circuit comprises at least a capacitor.

5. The converter according to claim 4, wherein one end of the capacitor is electrically connected with one end of the second winding.

6. The converter according to claim 4, wherein one end of the capacitor is electrically connected with one end of the third winding.

7. The converter according to claim 1, wherein an unbalanced signal I/O terminal of the unbalanced signal I/O circuit is electrically connected to a filter.

8. The converter according to claim 7, wherein the filter is a band-pass filter.

9. The converter according to claim 8, which is applied to an antenna system.

10. The converter according to claim 1, wherein the bias feeding circuit comprises at least a capacitor.

11. The converter according to claim 1, wherein the balanced signal I/O circuit comprises at least a balanced signal I/O terminal.

12. The converter according to claim 11, wherein the balanced signal I/O terminal of the balanced signal I/O circuit is electrically connected to an active component.

13. The converter according to claim 12, wherein the active component is an amplifier or a wireless transceiver.
